(19) United States
(12) Patent Application Publication
(10) Pub. No.: US 2026/0229408 A1
(43) Pub. Date: Aug. 6, 2026

(54) MULTILAYER BODY, CAPACITOR, ELECTRICAL CIRCUIT, CIRCUIT BOARD, APPARATUS, AND MULTILAYER BODY MANUFACTURING METHOD

(71) Applicant: Panasonic Intellectual Property Management Co., Ltd., Osaka (JP)

(72) Inventor: Manabu KANOU, Osaka (JP)

(21) Appl. No.: 19/576,563

(22) Filed: Mar. 24, 2026

Related U.S. Application Data
(63) Continuation of application No. PCT/JP2024/041893, filed on Nov. 26, 2024.

(30) Foreign Application Priority Data
May 17, 2024 (JP) 2024-081212

(51) Int. Cl. H01G 4/008; H01G 4/12; H01G 4/33; H05K 1/18

(52) U.S. Cl. CPC H01G 4/008; H01G 4/1254; H01G 4/33; H05K 1/18; H05K 2201/10015

(57) ABSTRACT

A multilayer body includes metallic tantalum and a dielectric layer. The dielectric layer is in contact with the metallic tantalum, and includes an oxide containing tantalum and tungsten. The dielectric layer has a relative permittivity of more than 27 and 41.7 or less at 120 Hz.

This application is a continuation of PCT/JP2024/041893 filed on Nov. 26, 2024, which claims foreign priority of Japanese Patent Application No. 2024-081212 filed on May 17, 2024, the entire contents of both of which are incorporated herein by reference.

### BACKGROUND OF THE INVENTION

### 1. Field of the Invention

The present invention relates to a multilayer body, a capacitor, an electrical circuit, a circuit board, an apparatus, and a multilayer body manufacturing method.

### 2. Description of Related Art

Techniques for improving permittivity by anodic oxidation have been known.

For example, JP H8-134696 A describes a high-permittivity composite oxide coating including 1 to 50 wt % of a central atom of an anion of an inorganic oxoacid salt, and the high-permittivity composite oxide coating is formed using a metal selected from metals belonging to Groups IIIa, IVa, and Va. This high-permittivity composite oxide coating has a relative permittivity at least twice the relative permittivity of an oxide of the metal. This high-permittivity composite oxide coating is manufactured by electrolytic anodic oxidation of the metal selected from metals belonging to Groups Illa, IVa, and Va in a non-aqueous electrolyte solution containing the inorganic oxoacid salt and having a water content of 5 wt % or less.

JP H10-154639 A describes a solid capacitor manufacturing method. This manufacturing method includes the steps of: forming a dielectric oxide coating layer on a surface of a metal substrate; and surface-treating the dielectric oxide coating layer. In the step of surface-treating the dielectric oxide coating layer, the portion with the dielectric oxide coating layer is immersed in an aqueous surface treatment solution containing phosphotungstic acid, molybdic acid, phosphomolybdic acid, or one or more salts thereof. For example, an aluminum anodic oxide coating layer is immersed in an aqueous phosphotungstic acid (H₃(PW₁₂O₄₀)) solution to form an inorganic oxide film layer of P₂O₅WO₃ on the aluminum anodic oxide coating layer. The metal substrate may be a tantalum foil, a sintered tantalum body, or the like.

JP H9-293647 A describes a solid tantalum electrolytic capacitor. A fine metal powder of tungsten-doped tantalum is used.

JP H10-275949 A describes a two-terminal nonlinear element. This two-terminal nonlinear element is produced by a method including forming an insulating film on a surface of a first conductive film formed of tantalum by anodic oxidation of the first conductive film in a predetermined non-aqueous chemical conversion solution.

In Masatoshi ISHIZUKA, Etsushi TSUJI, Yoshitaka AOKI, and Hiroki HABAZAKI, “Formation and Dielectric Properties of Anodic Films Formed on Ta—W Alloys at Various Formation Voltages”, Electrochemistry, 81, pp. 840-844 (2013) (Non Patent Literature 1), forming an anodic film on a magnetron-sputtered Ta—W alloy film is described. The anodic film is composed of two layers, which are a thin outer Ta₂O₅ film free of tungsten species and an inner layer including both tantalum species and tungsten species.

### SUMMARY OF THE INVENTION

The present disclosure provides a novel multilayer body including a predetermined dielectric layer on metallic tantalum.

A multilayer body of the present disclosure includes:
metallic tantalum; and
a dielectric layer in contact with the metallic tantalum and including an oxide containing tantalum and tungsten, wherein
the dielectric layer has a relative permittivity of more than 27 and 41.7 or less at 120 Hz.

The present disclosure can provide a novel multilayer body including a predetermined dielectric layer on metallic tantalum.

### BRIEF DESCRIPTION OF THE DRAWINGS

FIG. 1 is a cross-sectional view showing an example of the multilayer body of the present disclosure.

FIG. 2 is a potential-pH diagram showing states of tungsten in water.

FIG. 3 is a flowchart showing an example of the multilayer body manufacturing method of the present disclosure.

FIG. 4 is a cross-sectional view showing an example of the capacitor of the present disclosure.

FIG. 5 is a cross-sectional view showing another example of the capacitor of the present disclosure.

FIG. 6A schematically shows an example of the electrical circuit of the present disclosure.

FIG. 6B schematically shows an example of the circuit board of the present disclosure.

FIG. 6C schematically shows an example of the apparatus of the present disclosure.

FIG. 7 is a graph showing a relationship between the concentrations of oxygen and tungsten in a sample according to Example 1 and the depth from the surface of the sample.

### DETAILED DESCRIPTION

(Findings on which the Present Disclosure is Based)

According to the technique described in JP H8-134696 A, electrolytic anodic oxidation of a metal is performed in a non-aqueous electrolyte solution containing an inorganic oxoacid salt and having a water content of 5 wt % or less. Oxygen included in the oxoacid is substantially the only oxygen source required to form a dielectric film. Hence, for example, oxidization of metallic tantalum to a state corresponding to its highest oxidation number is difficult. This cannot be said to be advantageous from the view point of reducing current leakage upon application of voltage to the dielectric.

According to the technique described in JP H10-154639 A, a dielectric oxide coating layer needs to be formed by, for example, anodic oxidation before a surface treatment using an aqueous surface treatment solution containing phosphotungstic acid or the like.

According to the techniques described in JP H9-293647 A and Non Patent Literature 1, a dielectric including an oxide containing tungsten and tantalum is formed by anodic oxidation of an alloy of tantalum and tungsten. These techniques require an alloy of tantalum and tungsten, and that can impose constraints in terms of mass production.

The technique described in JP H10-275949 A relates to a two-terminal nonlinear element being an MIM element having a sufficiently small capacitance, and the MIM elements according to Examples have a relative permittivity of 17.7 to 20.5.

In view of such circumstances, the present inventor conducted intensive studies to determine whether it is possible to obtain a multilayer body in which a dielectric layer including an oxide containing tantalum and tungsten is on metallic tantalum, the dielectric layer having a given relative permittivity. After considerable trial and error, the present inventor has newly found a method for obtaining such a multilayer body. On the basis of this new finding, the present inventor has devised the multilayer body of the present disclosure.

### EMBODIMENTS

Embodiments of the present disclosure will be described hereinafter with reference to the drawings. The present disclosure is not limited to the following embodiments.

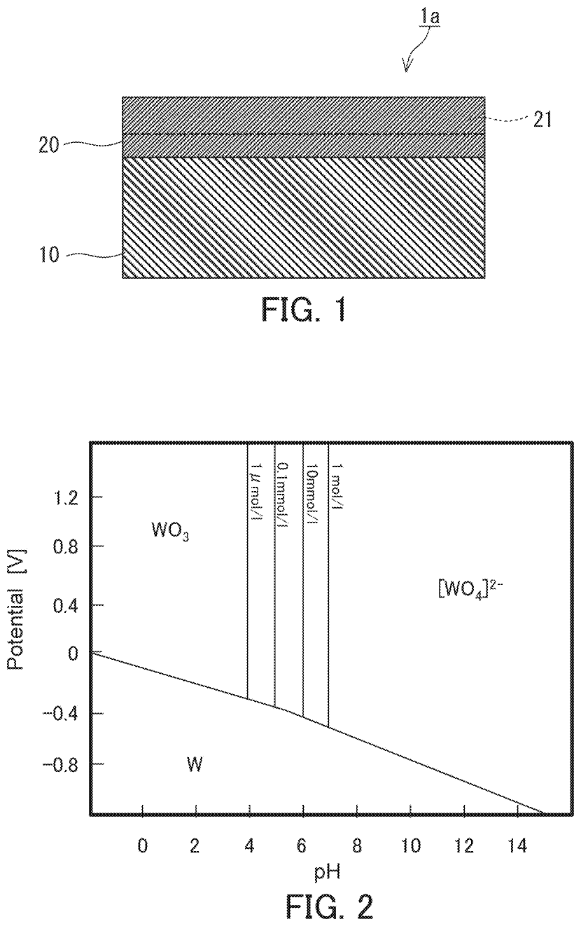

FIG. 1 is a cross-sectional view showing an example of the multilayer body of the present disclosure. As shown in FIG. 1, a multilayer body 1a includes metallic tantalum 10 and a dielectric layer 20. The dielectric layer 20 is in contact with the metallic tantalum 10, and includes an oxide containing tantalum and tungsten. The dielectric layer 20 has a relative permittivity of more than 27 and 41.7 or less at 120 Hz. The relative permittivity of the dielectric layer on the metallic tantalum can be determined, for example, by a method described in EXAMPLES.

Table 1 shows relative permittivities of metal oxides that can be formed by anodic oxidation of metals. As shown in Table 1, WO₃ obtained by anodic oxidation is amorphous, and has the highest relative permittivity among the amorphous metal oxides listed below. Hence, for example, if a metal oxide obtained by anodic oxidation of metallic tantalum includes tungsten in addition to tantalum, the dielectric layer obtained by anodic oxidation of metallic tantalum is expected to have a higher relative permittivity.

TABLE 1

| | | Relative |
|---|---|---|
| | State | permittivity ε |
| TiO₂ | Crystalline | 90 |
| WO₃ | Amorphous | 41.7 |
| Nb₂O₅ | Amorphous | 41.4 |
| Ta₂O₅ | Amorphous | 27.6 |
| ZrO₂ | Crystalline | 23 |
| HfO₂ | Crystalline | 21 |
| SiO₂ | Amorphous | 3.5 |
| Al₂O₃ | Amorphous | 9.8 |

FIG. 2 is a potential-pH diagram showing states of tungsten in water. As shown in FIG. 2, tungsten is water-soluble when the pH of an aqueous solution thereof is equal to or higher than a predetermined value in the range of 4 to 7 depending on the tungsten concentration in the aqueous solution. Therefore, when anodic oxidation of metallic tantalum is performed using an aqueous tungsten compound solution having a pH equal to or higher than a predetermined value in the range of 4 to 7, tungsten incorporated into a dielectric layer formed by the anodic oxidation can re-dissolve in the aqueous solution due to a reverse reaction. For example, in the technique described in Non Patent Literature 1, an anodic oxidation treatment of a Ta—W alloy is performed using an aqueous ammonium borate solution. The pH of an aqueous ammonium borate solution is generally approximately 8.2. Hence, it is thought that tungsten dissolves into the aqueous ammonium borate solution from the surface of the dielectric formed by the anodic oxidation treatment of the Ta—W alloy.

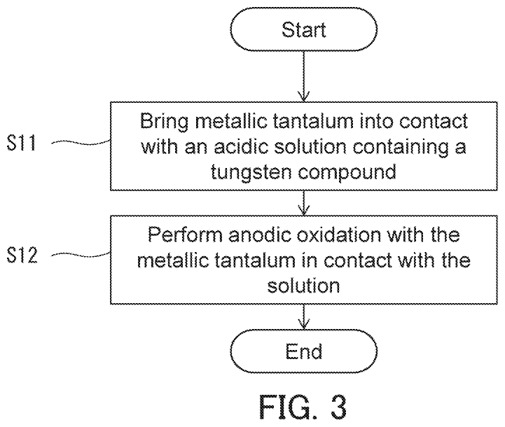

The multilayer body 1a can be produced, for example, by a method including (I) and (II) below. FIG. 3 is a flowchart showing an example of the method for manufacturing the multilayer body 1a.
(I) Bringing metallic tantalum into contact with an acidic solution containing a tungsten compound.
(II) Performing anodic oxidation of the metallic tantalum with the metallic tantalum in contact with the above solution.

First, in step S11, metallic tantalum is brought into contact with an acidic solution containing a tungsten compound. The solution is desirably an aqueous solution having a pH of 4 or less. In this case, tungsten is less likely to dissolve from a dielectric layer formed by anodic oxidation of the metallic tantalum, and the tungsten concentration in the dielectric layer is likely to be high. As a result, the relative permittivity of the dielectric layer is likely to be adjusted within the desired range. The pH of the aqueous solution may be 3.5 or less, 3.0 or less, 2.5 or less, 2.0 or less, 1.5 or less, or 1.0 or less.

The tungsten compound contained in the above solution is not limited to a particular compound. The above solution contains, for example, an electrolyte including a polytungstic acid or a polytungstate salt having an anion containing two or more tungsten atoms per molecule. In this case, tungsten is likely to be stably present in the solution, and the tungsten concentration in the dielectric layer is likely to be high. As a result, the relative permittivity of the dielectric layer is likely to be adjusted within the desired range.

The polytungstic acid or the polytungstate salt desirably has a heteroatom having a valence of three or greater. In this case, the pH of the aqueous solution is likely to be low. Examples of the heteroatom include phosphorus and silicon.

The concentration of the tungsten compound in the above solution is not limited to a particular value. The concentration thereof is, for example, 0.5 mass % or more. In this case, the tungsten concentration in the dielectric layer is likely to be high, and the relative permittivity of the dielectric layer is likely to be adjusted within the desired range.

The concentration of the tungsten compound in the above solution is desirably 1 mass % or more, more desirably 2 mass % or more, even more desirably 2.5 mass % or more. The concentration thereof may be 5 mass % or more, 10 mass % or more, 15 mass % or more, or 20 mass % or more. The concentration thereof is, for example, 50 mass % or less, and may be 45 mass % or less, 40 mass % or less, 35 mass % or less, or 30 mass % or less. The concentration thereof is, for example, 0.5 mass % or more and 50 mass % or less, and is desirably 1 mass % or more and 50 mass % or less, more desirably 2 mass % or more and 50 mass % or less, even more desirably 2.5 mass % or more and 50 mass % or less.

The above solution satisfies, for example, at least one requirement selected from the group consisting of (i) and (ii) below. Because of this, the tungsten concentration in the dielectric layer is likely to be high, and the relative permittivity of the dielectric layer is likely to be adjusted within the desired range. A heteropoly tungstic acid is a polytungstic acid whose anion is an oxoacid ion including an oxoacid of an element (heteroatom) other than Group V elements and Group VI elements (V, Nb, Ta, Mo, and W).
(i) The solution contains an electrolyte including a heteropoly tungstic acid or a heteropoly tungstate salt having an anion containing two or more tungsten atoms per molecule.
(ii) The concentration of the tungsten compound in the solution is 0.5 mass % or more.

Next, in step S12, anodic oxidation of the metallic tantalum is performed with the metallic tantalum in contact with the above solution. For example, while the metallic tantalum and a counter electrode are disposed in the solution with a predetermined distance therebetween, the anodic oxidation is performed by applying a predetermined voltage between the metallic tantalum and the counter electrode. For example, the metallic tantalum is used as an anode, and platinum is used as a cathode. An anion, such as an oxide ion, attracted toward the metallic tantalum as an anode and ionized tantalum are bonded to form an oxide of tantalum. During the formation process, the tungsten contained in the solution is incorporated into the dielectric layer. The dielectric layer 20 including an oxide containing tantalum and tungsten is formed in this manner on the metallic tantalum 10 to give the multilayer body 1a. As described above, the dielectric layer 20 is, for example, an anodic film.

The dielectric layer 20 may be produced by a method, such as sputtering, other than anodic oxidation. The dielectric layer 20 may be a sputtered film.

A relative permittivity of the dielectric layer 20 may be, for example, 28 or more or 29 or more, and may be 40 or less.

An average tungsten concentration in the dielectric layer 20 is not limited to a particular value. The average is, for example, 0.1 mass % or more and 20 mass % or less. In this case, the dielectric layer 20 is likely to have a desired relative permittivity. Moreover, oxygen vacancies are less likely to occur in the dielectric layer 20, and a product including the multilayer body 1a is likely to have a high durability. The average tungsten concentration in the dielectric layer 20 may be 0.15 mass % or more, or 0.2 mass % or more, and may be 15 mass % or less, 10 mass % or less, 5 mass % or less, 4 mass % or less, 3 mass % or less, 2 mass % or less, or 1 mass % or less. The average tungsten concentration in the dielectric layer 20 can be determined, for example, by a method described in EXAMPLES.

According to measurement of the dielectric layer 20 by time-of-flight secondary ion mass spectrometry (TOF-SIMS), a signal intensity of an ion derived from tungsten is, for example, lower than a signal intensity of an ion derived from tantalum oxide.

A thickness of the dielectric layer 20 is not limited to a particular value. The thickness is, for example, 10 nm or more and 1000 nm or less. The thickness of the dielectric layer 20 may be determined, for example, based on a result of TOF-SIMS measurement or observation of a cross-section of the dielectric layer with an electron microscope, such as a scanning electron microscope (SEM) or a transmission electron microscope (TEM).

The dielectric layer 20 includes, for example, a portion 21. The portion 21 has a tungsten concentration of 0.15 mass % or more, and has a thickness of 10 nm or more.

In this case, the dielectric layer 20 is more likely to have a desired relative permittivity, and a product including the multilayer body 1a is likely to have a high durability. The thickness of the portion 21 may be 20 nm or more, 50 nm or more, or 100 nm or more, and may be 1000 nm or less, 500 nm or less, or 200 nm or less.

The tungsten concentration in the dielectric layer 20 may, for example, continuously or non-continuously decrease with increasing distance from a surface of the dielectric layer 20 (a surface out of contact with the metallic tantalum 10) in a thickness direction of the dielectric layer 20. The dielectric layer 20 may include a portion where the tungsten concentration increases with increasing distance from the surface of the dielectric layer 20.

The shape of the metallic tantalum 10 is not limited to a particular shape. The metallic tantalum 10 may be in a shape of, for example, a plate or a foil, may be a shape of a particle or a fiber, or may be a porous body.

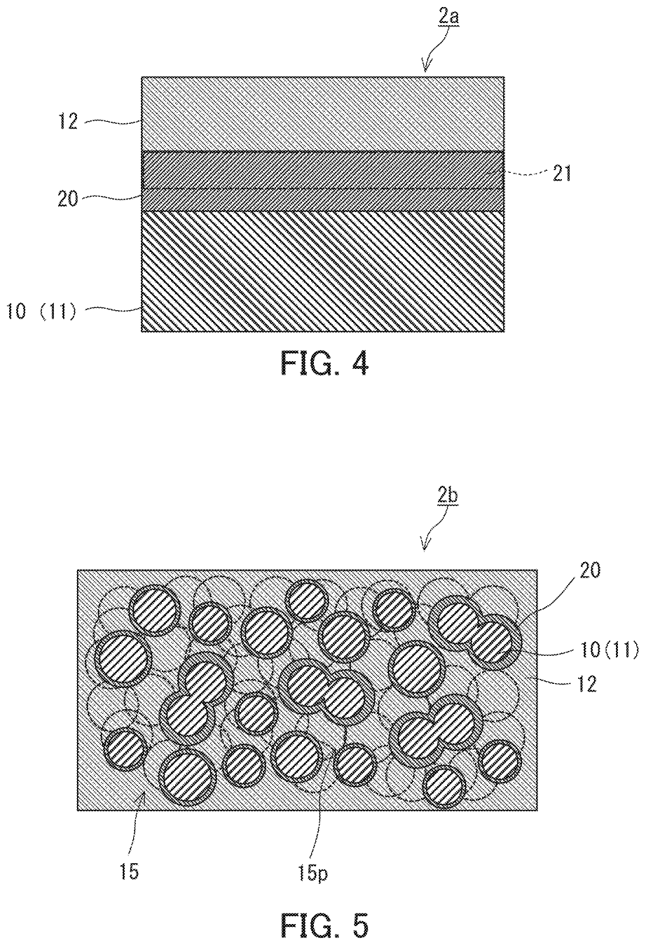

FIG. 4 is a cross-sectional view showing an example of the capacitor of the present disclosure. As shown in FIG. 4, a capacitor 2a includes a first electrode 11 including the metallic tantalum 10, a second electrode 12, and the dielectric layer 20. The dielectric layer 20 is disposed between the first electrode 11 and the second electrode 12. The dielectric layer 20 includes an oxide containing tantalum and tungsten. The dielectric layer 20 has a relative permittivity of more than 27 and 41.7 or less at 120 Hz. With such a configuration, the capacitor 2a is likely to have a high capacitance.

The capacitor 2a can be produced, for example, by forming or disposing the second electrode 12 on the surface of the dielectric layer 20 of the multilayer body 1a. Because of this, the dielectric layer 20 of the capacitor 2a can have a structure and properties derived from the dielectric layer 20 of the multilayer body 1a.

The material of the second electrode 12 is not limited to a particular material as long as the second electrode 12 has electrical conductivity. The second electrode 12 may include, for example, a valve metal, such as aluminum, tantalum, niobium, or bismuth, a noble metal, such as gold or platinum, or nickel. The second electrode 12 may include a carbon material, such as graphite.

In the capacitor 2a, the surface of the dielectric layer 20 may be in contact with an electrolyte. In this case, the second electrode 12 may include the electrolyte. The electrolyte is not limited to a particular electrolyte. The electrolyte includes, for example, at least one selected from the group consisting of an electrolyte solution, a solid electrolyte, and an electrically conductive polymer. Examples of the electrically conductive polymer include polypyrrole, a polythiophene, polyaniline, and derivatives of these. The electrolyte may be a manganese compound, such as manganese oxide.

FIG. 5 is a cross-sectional view showing another example of the capacitor of the present disclosure. A capacitor 2b shown in FIG. 5 is configured in the same manner as the capacitor 2a unless otherwise described. The components of the capacitor 2b that are the same as or correspond to the components of the capacitor 2a are denoted by the same reference characters, and detailed descriptions of such components are omitted. The description given for the capacitor 2a is applicable to the capacitor 2b unless there is a technical inconsistency.

As shown in FIG. 5, in the capacitor 2b, the dielectric layer 20 and the first electrode 11 form a porous body 15. The second electrode 12 fills a pore 15p of the porous body 15. In this configuration, the first electrode 11 has an increased surface area, and thus the capacitor 2b is likely to have a higher capacitance.

The porous body 15 is obtained, for example, by performing anodic oxidation with the metallic tantalum 10 having a porous structure in contact with an acidic solution containing a tungsten compound. The metallic tantalum 10 having a porous structure is obtained, for example, by etching of a metallic tantalum foil or sintering of metallic tantalum powder.

In the capacitor 2b, the second electrode 12 includes, for example, an electrolyte. The electrolyte includes, for example, at least one selected from the group consisting of an electrolyte solution, a solid electrolyte, and an electrically conductive polymer. Examples of the electrically conductive polymer include polypyrrole, a polythiophene, polyaniline, and derivatives of these. The electrolyte may be a manganese compound, such as manganese oxide.

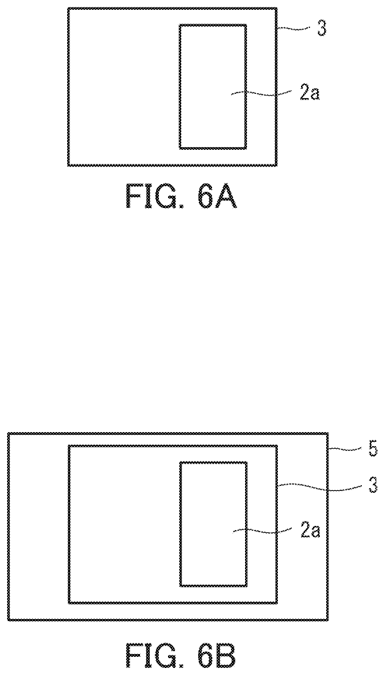

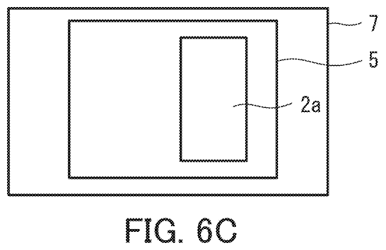

FIG. 6A schematically shows an example of the electrical circuit of the present disclosure. An electrical circuit 3 includes the capacitor 2a. The electrical circuit 3 may be an active circuit or a passive circuit. The electrical circuit 3 may be a discharging circuit, a smoothing circuit, a decoupling circuit, or a coupling circuit. Since the electrical circuit 3 includes the capacitor 2a, the electrical circuit 3 is likely to exhibit desired performance. For example, noise is likely to be reduced in the electrical circuit 3. The electrical circuit 3 may include the capacitor 2b.

FIG. 6B schematically shows an example of the circuit board of the present disclosure. As shown in FIG. 6B, a circuit board 5 includes the capacitor 2a. For example, the circuit board 5 includes the electrical circuit 3 including the capacitor 2a. Since the circuit board 5 includes the capacitor 2a, the circuit board 5 is likely to exhibit desired performance. The circuit board 5 may be an embedded board or a motherboard. The circuit board 5 may include the capacitor 2b.

FIG. 6C schematically shows an example of the apparatus of the present disclosure. As shown in FIG. 6C, an apparatus 7 includes the capacitor 2a. The apparatus 7 includes, for example, the circuit board 5 including the capacitor 2a. Since the apparatus 7 includes the capacitor 2a, the apparatus 7 is likely to exhibit desired performance. The apparatus 7 may be an electronic device, a communication device, a signal-processing device, or a power-supply device. The apparatus 7 may be a server, an AC adapter, an accelerator, or a flat-panel display such as a liquid crystal display (LCD). The apparatus 7 may be a USB charger, a solid-state drive (SSD), an information terminal such as a PC, a smartphone, or a tablet PC, or an Ethernet switch. The apparatus 7 may include the capacitor 2b.

### (Supplement)

According to the above description, the following techniques are disclosed.

### (Technique 1)

A multilayer body including:
metallic tantalum; and
a dielectric layer in contact with the metallic tantalum and including an oxide containing tantalum and tungsten, wherein
the dielectric layer has a relative permittivity of more than 27 and 41.7 or less at 120 Hz.

### (Technique 2)

The multilayer body according to Technique 1, wherein an average tungsten concentration in the dielectric layer is 0.1 mass % or more and 20 mass % or less.

### (Technique 3)

The multilayer body according to Technique 1 or 2, wherein the dielectric layer includes a portion having a tungsten concentration of 0.15 mass % or more and having a thickness of 10 nm or more.

### (Technique 4)

A capacitor including:
a first electrode including metallic tantalum;
a second electrode; and
a dielectric layer disposed between the first electrode and the second electrode and including an oxide containing tantalum and tungsten, wherein
the dielectric layer has a relative permittivity of more than 27 and 41.7 or less at 120 Hz.

### (Technique 5)

An electrical circuit including the capacitor according to Technique 4.

### (Technique 6)

A circuit board including the capacitor according to Technique 4.

### (Technique 7)

An apparatus including the capacitor according to Technique 4.

### (Technique 8)

A multilayer body manufacturing method including:
bringing metallic tantalum into contact with an acidic solution containing a tungsten compound; and
performing anodic oxidation of the metallic tantalum with the metallic tantalum in contact with the solution.

### (Technique 9)

The multilayer body manufacturing method according to Technique 8, wherein the solution satisfies at least one requirement selected from the group consisting of (i) and (ii) below:
(i) the solution contains an electrolyte including a heteropoly tungstic acid or a heteropoly tungstate salt having an anion containing two or more tungsten atoms per molecule; and
(ii) a concentration of the tungsten compound in the solution is 0.5 mass % or more.

### (Technique 10)

The multilayer body manufacturing method according to Technique 8 or 9, wherein the solution is an aqueous solution having a pH of 4 or less.

### (Technique 11)

The multilayer body manufacturing method according to any one of Techniques 8 to 10, wherein the solution satisfies the requirement (i).

### (Technique 12)

The multilayer body manufacturing method according to any one of Techniques 8 to 10, wherein the solution satisfies the requirement (ii).

### (Technique 13)

The multilayer body manufacturing method according to any one of Techniques 8 to 12, wherein the solution satisfies the requirements (i) and (ii).

### (Technique 14)

The multilayer body manufacturing method according to Technique 8, wherein the heteropoly tungstic acid or the heteropoly tungstate salt has a heteroatom having a valence of three or greater.

### EXAMPLES

Hereinafter, the present disclosure will be described in more detail with reference to examples. The examples given below are just examples, and the present disclosure is not limited to them.

### Example 1

Ultrasonic cleaning was performed for 10 minutes with a flat plate of metallic tantalum immersed in an acetone-filled container, thereby washing the surface of the metallic tantalum. After that, acetone on the surface of the metallic tantalum was evaporated, and the surface of the metallic tantalum was washed with pure water. The metallic tantalum was then dried in air.

The above metallic tantalum and metallic tantalum as a counter electrode were disposed in a 100 mmol/L (millimoles per liter) aqueous H₄SiW₁₂O₄₀ solution with a predetermined distance therebetween. The pH of the aqueous solution was less than 1. The H₄SiW₁₂O₄₀ concentration in this aqueous solution was 22 mass %. The portion of the metallic tantalum above the surface of the aqueous solution was connected to a positive electrode of a power-supply device, while the portion of the metallic tantalum as a counter electrode above the surface of the aqueous solution was connected to a negative electrode of the power-supply device. A current was carried under constant voltage from the power-supply device, so that a voltage of 95 V was applied for 10 hours between the metallic tantalum connected to the positive electrode and the metallic tantalum as a counter electrode. This caused an electrochemical reaction on the surface of the metallic tantalum as an anode to give an oxidized film. The metallic tantalum with the oxidized film was taken out of the aqueous solution, washed with pure water, and then dried in air. A sample according to Example 1 in which a dielectric film being an oxidized film was provided on the surface of metallic tantalum was obtained in this manner.

### Example 2

A sample according to Example 2 was obtained in the same manner as in Example 1, except that a 100 mmol/L aqueous H₃PW₁₂O₄₀ solution was used instead of the aqueous H₄SiW₁₂O₄₀ solution. The pH of the aqueous H₃PW₁₂O₄₀ solution was less than 1. The H₃PW₁₂O₄₀ concentration in this aqueous solution was 22 mass %.

### Example 3

A sample according to Example 3 was obtained in the same manner as in Example 1, except that the H₄SiW₁₂O₄₀ concentration in the aqueous H₄SiW₁₂O₄₀ solution was changed to 10 mmol/L. In Example 3, the pH of the aqueous H₄SiW₁₂O₄₀ solution was 1.4. The H₄SiW₁₂O₄₀ concentration in this aqueous solution was 2.8 mass %.

### Comparative Example 1

A sample according to Comparative Example 1 was obtained in the same manner as in Example 1, except that an aqueous H₃PO₄ solution was used instead of the aqueous H₄SiW₁₂O₄₀ solution.

### (Thickness Measurement and Elemental Composition Analysis)

Cross-sections of the samples according to Example 1, Example 2, and Example 3 were observed using a scanning electron microscope (SEM) JSM 7900F manufactured by JEOL Ltd. In this observation, the cross-section of each of the samples according to Examples was polished using a cross-section polisher, and the thickness of the dielectric film was determined by observing the cross-section in a direction perpendicular to the cross-section. Furthermore, energy dispersive X-ray fluorescence spectrometry (EDX) was performed using a device supplied with the SEM, and the tungsten concentrations at four points were averaged to smooth errors at the spot points, thereby calculating the tungsten concentration in the dielectric film. Table 2 shows the results. Since the spot diameter was approximately 100 nm to 200 nm for the apparatus used to determine the concentration and smoothing was performed for more than one point, the concentration is considered to correspond to the average tungsten concentration in the dielectric film.

TABLE 2

| | | Electrolyte | Electrolyte | | |
|---|---|---|---|---|---|
| | | concentration | concentration | | |
| | | in aqueous | in aqueous | Thickness of | Tungsten |
| | Tungsten | solution | solution | dielectric | concentration |
| | compound | [mmol/L] | [mass %] | film [nm] | [mass %] |
| Example 1 | H₄SiW₁₂O₄₀ | 100 | 22 | 183 | 2.9 |
| Example 2 | H₃PW₁₂O₄₀ | 100 | 22 | 179 | 2.1 |
| Example 3 | H₄SiW₁₂O₄₀ | 10 | 2.8 | 175 | 0.5 |

### (Measurement of Elemental Concentration Distribution)

Glow-discharge optical emission spectrometry (GD-OES) was performed using a GD-OES device GD-Profiler 2 manufactured by HORIBA, Ltd. for a specimen produced from a portion of the surface of the dielectric film of each of the samples according to Example 1 and Example 2. In the GD-OES, the specimen was subjected to argon gas sputtering under predetermined conditions to give an emission spectrum. The emission spectrum was converted into a mass concentration using software supplied with GD-Profiler 2. Since GD-OES is a semi-quantitative analytical method, absolute values of the concentrations of elements of interest are not always highly reliable. Therefore, the GD-OES measurement results are used only to evaluate concentration distributions of elements of interest in the thickness direction of the dielectric films of the samples according to Examples. The above values obtained by EDX are employed as the average tungsten concentrations in the dielectric films.

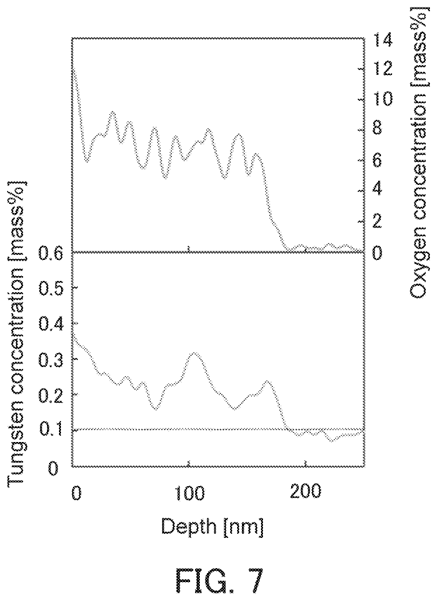

FIG. 7 is a graph showing a relationship between the concentrations of oxygen and tungsten in the sample according to Example 1 and the depth from the surface of the sample. This graph was obtained by GD-OES of the sample according to Example 1. In FIG. 7, the upper graph shows a relationship between the oxygen concentration and the depth from the surface of the sample. In this graph, the vertical axis represents the oxygen concentration [mass %], and the horizontal axis represents the depth from the surface of the sample. In FIG. 7, the lower graph shows a relationship between the tungsten concentration and the depth from the surface of the sample. In this graph, the vertical axis represents the tungsten concentration [mass %], and the horizontal axis represents the depth from the surface of the sample.

In the lower graph of FIG. 7, a portion corresponding to a tungsten concentration of 0.1 mass % or less is considered to be a background noise attributable to similarity between an emission spectrum of Ta and an emission spectrum of W. The thickness of the dielectric film of the sample according to Example 1 is 183 nm as shown in Table 2. In the graph of FIG. 7 as well, the oxygen concentration and the tungsten concentration were significantly low in a depth range of 180 nm or more. In the lower graph of FIG. 7, the tungsten concentration is higher than the background noise in the depth range corresponding to the dielectric film, and this indicates that tungsten is present over the entire thickness of the dielectric film. In other words, the dielectric film of the sample according to Example 1 includes an oxide containing tantalum and tungsten. Likewise, it is inferred that tungsten is present over the entire thickness of the dielectric film also in the dielectric films of the samples according to Example 2 and Example 3.

### (Measurement of Permittivity)

The sample according to Example 1 was immersed in a sulfuric acid solution, and dielectric properties of the dielectric film of each of the samples according to Example 1, Example 2, Example 3, and Comparative Example 1 were evaluated by an AC impedance method using platinum as a counter electrode. Table 3 shows the results. Modulab XM manufactured by Solartron Analytics was used for the AC impedance measurement. For this evaluation, an alternating voltage having an amplitude of 10 mV to 100 mV and a frequency range of 1 MHz to 0.1 Hz was applied to the sample according to Example 1, and an electrostatic capacitance C was calculated from a complex impedance at 120 Hz. A relative permittivity & was calculated by the following equation (1) using the calculated electrostatic capacitance C, the thickness t calculated for the dielectric film by SEM observation, and an electric constant co being a permittivity of vacuum. In the equation (1), S represents the surface area of the metallic tantalum on which the dielectric film was formed.

$$ε = ( C \cdot t ) / ( {ε}_{0} S ) \qquad Equation ( 1 )$$

TABLE 3

| | | Ratio of relative permittivity ε to |
|---|---|---|
| | Relative | relative permittivity ε of |
| | permittivity ε | Comparative Example 1 |
| Example 1 | 30.8 | 1.14 |
| Example 2 | 29.4 | 1.09 |
| Example 3 | 28.2 | 1.04 |
| Comparative | 27.0 | 1 |
| Example 1 | | |

As shown in Table 3, comparison of Examples 1 to 3 with Comparative Example 1 reveals that inclusion of tungsten in the dielectric film increases the relative permittivity of the dielectric film. Moreover, according to Table 2, the tungsten concentration in the dielectric film of the sample according to Example 1 is higher than that in the dielectric film of the sample according to Example 2. Furthermore, the tungsten concentration in the dielectric film of the sample according to Example 2 is higher than that in the dielectric film of the sample according to Example 3. Comparison of Example 1 with Example 2 and comparison of Example 2 with Example 3 reveal that a high tungsten concentration in the dielectric film is advantageous in terms of increasing the relative permittivity of the dielectric film.

The multilayer body of the present disclosure can be suitably used in electronic components, such as capacitors.

What is claimed is:

1. A multilayer body comprising:
metallic tantalum; and
a dielectric layer in contact with the metallic tantalum and including an oxide containing tantalum and tungsten, wherein
the dielectric layer has a relative permittivity of more than 27 and 41.7 or less at 120 Hz.

2. The multilayer body according to claim 1, wherein an average tungsten concentration in the dielectric layer is 0.1 mass % or more and 20 mass % or less.

3. The multilayer body according to claim 1, wherein the dielectric layer includes a portion having a tungsten concentration of 0.15 mass % or more and having a thickness of 10 nm or more.

4. A capacitor comprising:
a first electrode including metallic tantalum;
a second electrode; and
a dielectric layer disposed between the first electrode and the second electrode and including an oxide containing tantalum and tungsten, wherein
the dielectric layer has a relative permittivity of more than 27 and 41.7 or less at 120 Hz.

5. An electrical circuit comprising the capacitor according to claim 4.

6. A circuit board comprising the capacitor according to claim 4.

7. An apparatus comprising the capacitor according to claim 4.

8. A multilayer body manufacturing method comprising:
bringing metallic tantalum into contact with an acidic solution containing a tungsten compound; and
performing anodic oxidation of the metallic tantalum with the metallic tantalum in contact with the solution, wherein
the solution satisfies at least one requirement selected from the group consisting of (i) and (ii) below:
(i) the solution contains an electrolyte including a heteropoly tungstic acid or a heteropoly tungstate salt having an anion containing two or more tungsten atoms per molecule; and
(ii) a concentration of the tungsten compound in the solution is 0.5 mass % or more.

9. The multilayer body manufacturing method according to claim 8, wherein the solution is an aqueous solution having a pH of 4 or less.

10. The multilayer body manufacturing method according to claim 8, wherein the solution satisfies the requirement (i).

11. The multilayer body manufacturing method according to claim 8, wherein the solution satisfies the requirement (ii).

12. The multilayer body manufacturing method according to claim 8, wherein the solution satisfies the requirements (i) and (ii).

13. The multilayer body manufacturing method according to claim 8, wherein the heteropoly tungstic acid or the heteropoly tungstate salt has a heteroatom having a valence of three or greater.
